(19) United States
(12) Patent Application Publication
(10) Pub. No.: US 2012/0138139 A1
(43) Pub. Date: Jun. 7, 2012

(54) DRY ETCHING METHOD OF SURFACE TEXTURE FORMATION ON SILICON WAFER

(75) Inventor: Young Kyu CHO, San Jose, CA (US)

(73) Assignee: INTEVAC, INC., Santa Clara, CA (US)

(21) Appl. No.: 13/287,049

(22) Filed: Nov. 1, 2011

Related U.S. Application Data
(60) Provisional application No. 61/409,064, filed on Nov. 1, 2010.

(51) Int. Cl. H01L 31/0236; H01L 21/306; H01L 21/302

(52) U.S. Cl. 136/256; 438/719; 438/712; 438/710; 438/706; 156/345.1; 156/345.31; 257/E21.214

(57) ABSTRACT

Systems and methods for improving surface reflectance of silicon wafers are disclosed. The systems and methods improve surface reflectance by forming a textured surface on the silicon wafer by performing surface oxidation and dry etching processes. The surface oxidation maybe performed using a dry oxygen plasma process. A dry etch process is performed to remove the oxide layer formed by the surface oxidation step and etch the Silicon layer with oxide masking. Dry etching enables black silicon formation, which minimizes or eliminates light reflection or scattering, eventually leading to higher energy conversion efficiency.

### PRIORITY

The present application claims priority to U.S. Provisional Application No. 61/409,064, filed Nov. 1, 2010, and entitled “DRY ETCHING METHOD OF SURFACE TEXTURE FORMATION ON SILICON WAFER,” the entirety of which is hereby incorporated by reference.

### BACKGROUND

1. Field

This invention relates to the art of silicon wafers for solar cells and, more particularly, to surface texture formation using a dry etch process.

2. Related Art

Solar cells, also known as photovoltaic (PV) cells, convert solar radiation into electrical energy. Solar cells are fabricated using semiconductor processing techniques, which typically, include, for example, deposition, doping and etching of various materials and layers. Typical solar cells are made on semiconductor wafers or substrates, which are doped to form p-n junctions in the wafers or substrates. Solar radiation (e.g., photons) directed at the surface of the substrate cause electron-hole pairs in the substrate to be broken, resulting in migration of electrons from the n-doped region to the p-doped region (i.e., an electrical current is generated). This creates a voltage differential between two opposing surfaces of the substrate. Metal contacts, coupled to electrical circuitry, collect the electrical energy generated in the substrate.

Semiconductor materials used to make solar cells are very reflective. To reduce the reflectivity of the solar cell, the surface of the solar cell that receives the solar radiation is textured. Decreasing the reflection at the surface increases the efficiency of the solar cell. Solar cells manufactured using conventional techniques (e.g., wet texture) to create the textured surface typically have a reflectance of about 27%, and an efficiency that is only on the order of about 12-18%. Solar cell efficiency improvement is critical to those who manufacture solar cell device in order for maximize the commercial value of solar cell. In addition, in case of conventional wet texturing method, wet chemicals need to be selected depending on the types of silicon wafers (e.g., mono crystal silicon wafer, multi crystal silicon) due to the chemical etching property dependency on crystal types. In order to achieve proper surface texturing, Mono crystal wafers usually requires Alkaline based chemicals, and multi crystal wafers requires Acid chemicals, while dry etching texturing result does not depend on wafer types, mono or multi crystal.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, a system is provided that includes a silicon etch chamber to perform a first etch process to remove a portion of a silicon oxide layer on a silicon wafer and a second etch process that is highly selective of silicon to oxide.

The system may also include an oxidation chamber to form the silicon oxide layer on a surface of a silicon wafer. The oxidation chamber may be a plasma oxidation chamber.

The oxidation chamber may be coupled to the silicon etch chamber so the silicon oxide layer is formed on the surface of the silicon wafer before the wafer enters the silicon etch chamber.

The system may also include a wafer loading chamber and a wafer unloading chamber. The system may also include a loadlock between the wafer loading chamber and the plasma oxidation chamber, and a loadlock between the silicon etch chamber and the wafer unloading chamber.

According to another aspect of the invention, a method of making a silicon wafer having a textured surface is provided that includes performing a first silicon etch process on a silicon wafer having an oxide layer; and performing a second silicon etch process on the silicon wafer, wherein the second silicon etch process is more selective etching of silicon to oxide. A solar cell made by this process is also provided.

The method may also include performing a surface oxidation process on a silicon wafer to grow the oxide layer before performing the first silicon etch process. The surface oxidation process may be a plasma oxidation.

The first and second silicon etch processes my be dry etching. The dry etching may be one of reactive ion etching, plasma etching and physical sputtering. The second silicon etch process may be an anisotropic etch process.

According to a further aspect of the invention, a method is provided that includes etching a silicon oxide layer on a silicon wafer having defect sites and non-defect sites to remove at least the portion of the silicon oxide layer over the non-defect sites; and selectively etching the wafer. A solar cell made by this process is also provided.

The method may also include growing the silicon oxide layer before etching the silicon oxide layer. Growing the silicon oxide layer may include oxidizing the silicon wafer. The silicon oxide layer may be thicker over the defect sites than over the non-defect sites.

Etching the silicon oxide layer may include dry etching the silicon oxide layer. Selectively etching the wafer may include dry etching the wafer.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 is perspective view illustrating a solar cell having an ideal texture surface according to one embodiment of the invention. This drawing shows typical Passivated Emitter Rear Contact (PERC) solar cell structure which was developed by University of New South Wales (UNSW) with wet textured front surface on mono crystal silicon wafer.

FIG. 2 is a perspective view of a solar cell having a typical solar cell texture surface on multi crystal silicon wafer according to one embodiment of the invention.

FIG. 3 is a conceptual and schematic view illustrating a Dry etch system for making a solar cell surface texture according to one embodiment of the invention.

FIG. 4 is a flow diagram illustrating a process sequence for making a solar cell surface texture according to one embodiment of the invention.

FIGS. 5A-5B are photographs illustrating results of dry texturing with pre oxidation, and FIGS. 5C-5D are photographs illustrating results of dry texturing with no pre oxidation.

FIGS. 6A-6B illustrate the wafer surface as cut, FIGS. 6C-6D illustrate the wafer surface after saw damage layer removal and wet chemical texturing, and FIGS. 6E-6H illustrating the wafer surface after dry etch texturing.

FIG. 7 is a graph illustrating the improvement in reflectance achieved with wet texturing and dry texturing processes according to embodiments of the invention.

FIG. 8A illustrates the wafer surface after wet texture, FIGS. 8B-8C illustrate the wafer surface after dry texturing etch, and FIG. 8D illustrates the wafer surface after residual removal.

### DETAILED DESCRIPTION

Embodiments of the invention are directed to systems and methods for improving surface reflectance of silicon wafers. The systems and methods improve surface reflectance by forming a textured surface on the silicon wafer by performing surface oxidation and dry etching processes. In one embodiment, the surface oxidation is performed using oxygen plasma. Selective oxidation occurs between defect sites and non-defect sites. The etching chemistry is then switched to highly selective etching of silicon to silicon oxide. Dry etching enables nano-scale textured surface formation, which minimizes or eliminates light reflection or scattering.

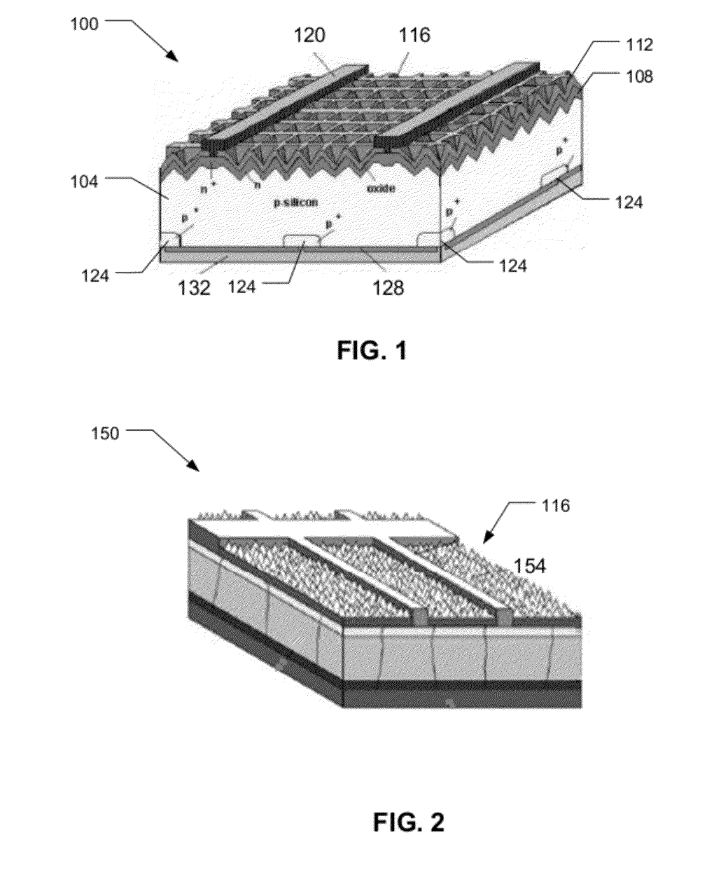

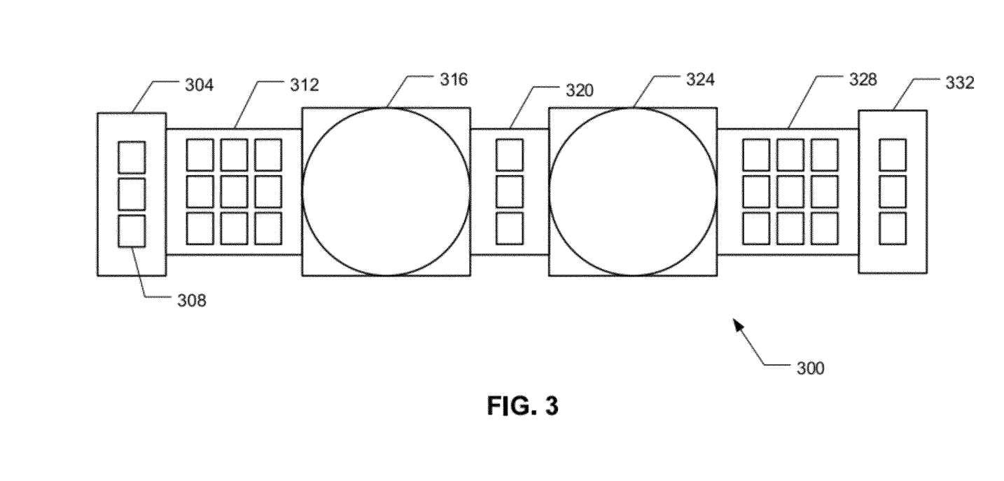

FIG. 1 illustrates a typical PERC solar cell 100, and FIG. 2 illustrates a typical multi crystal solar cell 150. As shown in FIGS. 1 and 2, the solar cell 100 includes a substrate 104 which is typically formed of silicon. A n-doped layer 108 is formed at a surface of the substrate 104, and a dielectric layer 112 (e.g., an oxide) is formed over the n-doped layer 108, which together form a substrate surface 116. Metal contacts 120 are formed on the surface 116. P-doped regions 124 are formed in the substrate 104, and a dielectric layer 128 and metal contacts 132 are formed over the p-doped regions 124. As shown in FIG. 1, the ideal solar cell 100 has a surface 116 that has a periodic inverted pyramid structure. As shown in FIG. 2, on the other hand, the textured surface 116 of the typical solar cell 150 often includes micro-cavities or micro-grooves.

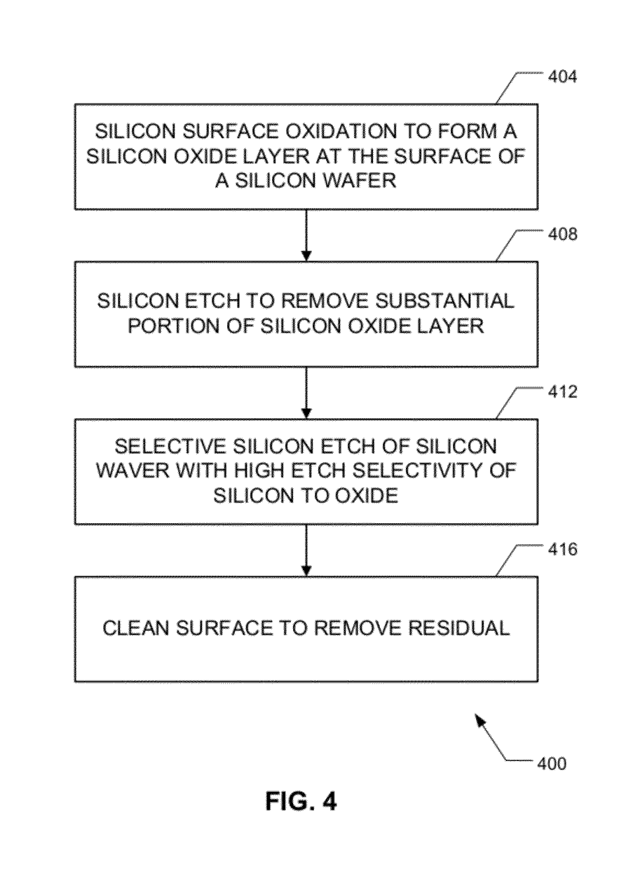

FIG. 3 illustrates a system 300 for forming the improved texture according to embodiments of the invention. As shown in FIG. 3, the system 300 includes a wafer loading chamber 304 for loading wafers 308, a buffer stage/loadlock 308, an oxidation chamber 316, an interface 320, a silicon etch chamber 324, a buffer stage/loadlock 328, and a wafer unloading chamber 332.

The wafer 308 enters the system 300 at loading chamber 304, and passes through the buffer stage/loadlock 308 before entering the plasma oxidation chamber 316. The wafer 308 undergoes an oxidation process in the plasma oxidation chamber 316. The wafer 308 then passes through interface 320 before entering the silicon etch chamber 324. The wafer 308 undergoes a dry etch process in the silicon etch chamber 324. After the dry etch process, the wafer 308 passes through the buffer stage/loadlock 328 before exiting the system 300 through the wafer unloading chamber 332.

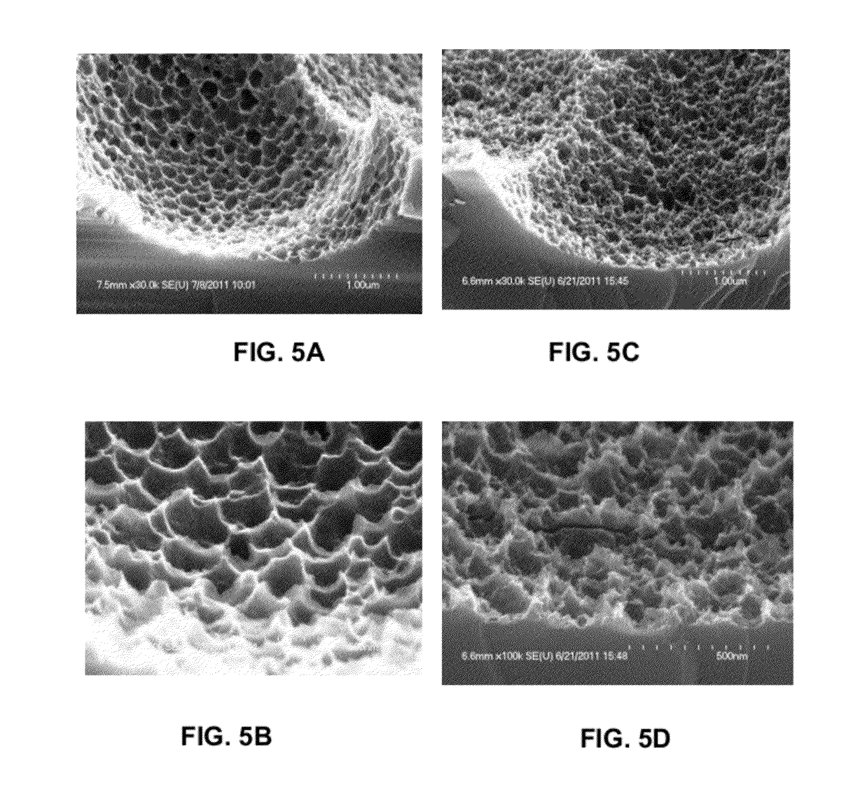

FIG. 4 illustrates a flow diagram of a process for forming the textured surface 400 according to one embodiment of the invention. As shown in FIG. 4, the process 400 begins by performing a silicon surface oxidation process 404 to form a silicon oxide layer at the surface of the silicon wafer. In one embodiment, the silicon surface oxidation process 404 is a dry oxygen plasma process. It will be appreciated that other oxidation processes be used, such as for example, a wet oxidant chemistry oxidation, a thermal process oxidation, such as thermal oxidation and RTP oxidation, and the like.

When the silicon oxide layer is former, a thicker oxidation layer is formed at defect sites than at non-defect sites. The silicon wafer surface has a micro lattice boundary and lattice defect sites all over the surface, and it is usually easier to get a chemical reaction at the defect site. In this case, where the silicon surface is exposed to an oxidant chemistry, a thicker oxidation layer is formed at the defect site. In one embodiment, the average thickness of the oxide layer formed with the oxidation process is about 25 Å thick. It will be appreciated that the thickness may be any value or range of values between about 20 and about 50 Å.

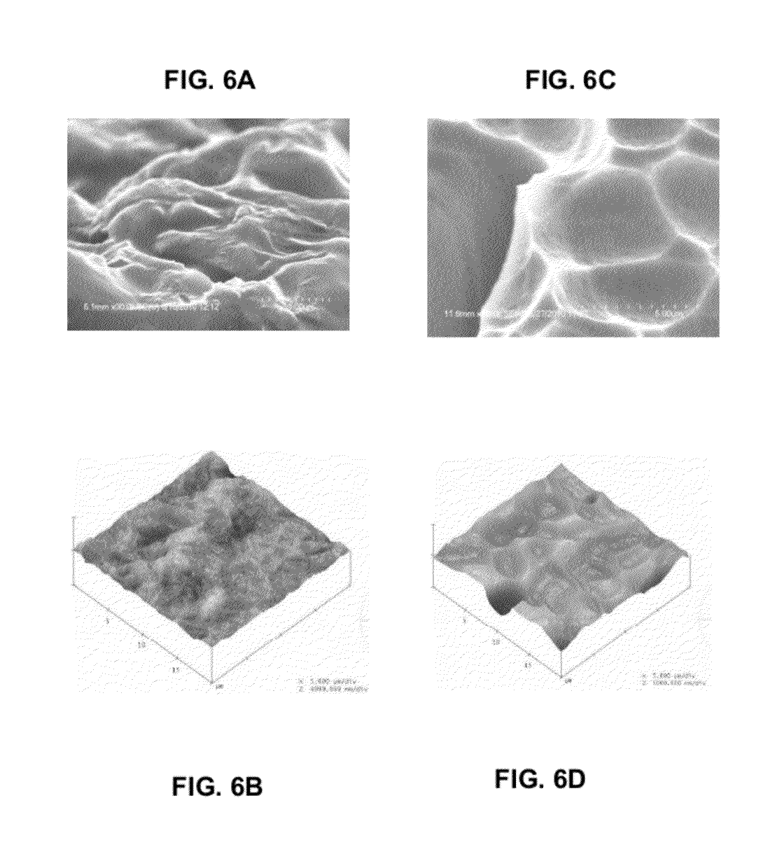

As shown in FIGS. 5A-5B, the oxidation process results in a surface having a reflectance of about 8.5%. In contrast, if no oxidation process is performed, the reflectance of the silicon wafer is about 10%, as shown in FIGS. 5C-5D. In the case of no plasma oxidation, about 10 to about 15 Å of the silicon oxide layer exists due to native oxidation and wet oxidation during the wet texturing process.

With reference back to FIG. 4, the process 400 continues by etching the silicon wafer 408 to remove a substantial portion of the silicon oxide layer formed by the oxidation process 404. In one particular embodiment, the entire oxidation layer over the non-defect sites is removed during the etch process 408, but the portion of the oxidation layer that is thicker over the defect sites remains. During etch 408, a major part of oxide layer (thin layer) is removed and only the thicker oxide area is left. It will be appreciated that a substantial portion of the oxidation layer over the non-defect sites may be removed. In embodiments of the present invention, the etch process 408 is a dry etch process. Dry etching refers to the removal of material by exposing the material to a bombardment of ions that dislodge portions of the material from the exposed surface. Exemplary dry etch techniques include reactive ion etching (RIE), plasma etching, physical sputtering, and the like. In one particular embodiment, the dry etch step is fluorine-based. For example, the dry etch step may use a mixture of SF₆ and O₂. An exemplary process occurs for about 60 seconds or less at 100 mT at room temperature.

The process 400 continues by selectively etching the wafer 412 with high silicon etch selectivity to oxide. The etch process condition has high silicon etch selectivity to oxide (i.e., a high silicon etch rate and a low oxide etch rate). The remaining oxide layer (i.e., the oxide layer over the defect sites that is not removed in the etch step 408) works as a mask during the silicon etching step 412. Once the silicon surface is exposed to plasma chemistry at the non defect on silicon, etching of silicon begins while silicon under the remaining oxide area remains intact during etch 412. Process step 412 uses the non-uniform oxide thickness characteristic for masking pattern generation. Because the silicon surface has a lot of irregular defect sites, and the oxide layer is thicker at the defect sites than the non defect silicon surface, oxygen penetrates more easily at the defect site than the normal (non-defect) site. In some embodiments, the same process conditions are applied during both process steps 408 and 412. Etch 412 may also be a dry etching process. This dry etching process typically etches anisotropically with minimal loss of the oxide mask layer. In some embodiments, the selective etching continues as long as the oxide layer exists. In one embodiment, the silicon etch step is fluourine-based as well.

The process 400 may optionally continue by cleaning the silicon wafer to remove residuals 416. In one particular embodiment, a diluted HF solution is used to clean the wafer by dissolving any remaining silicon oxide material.

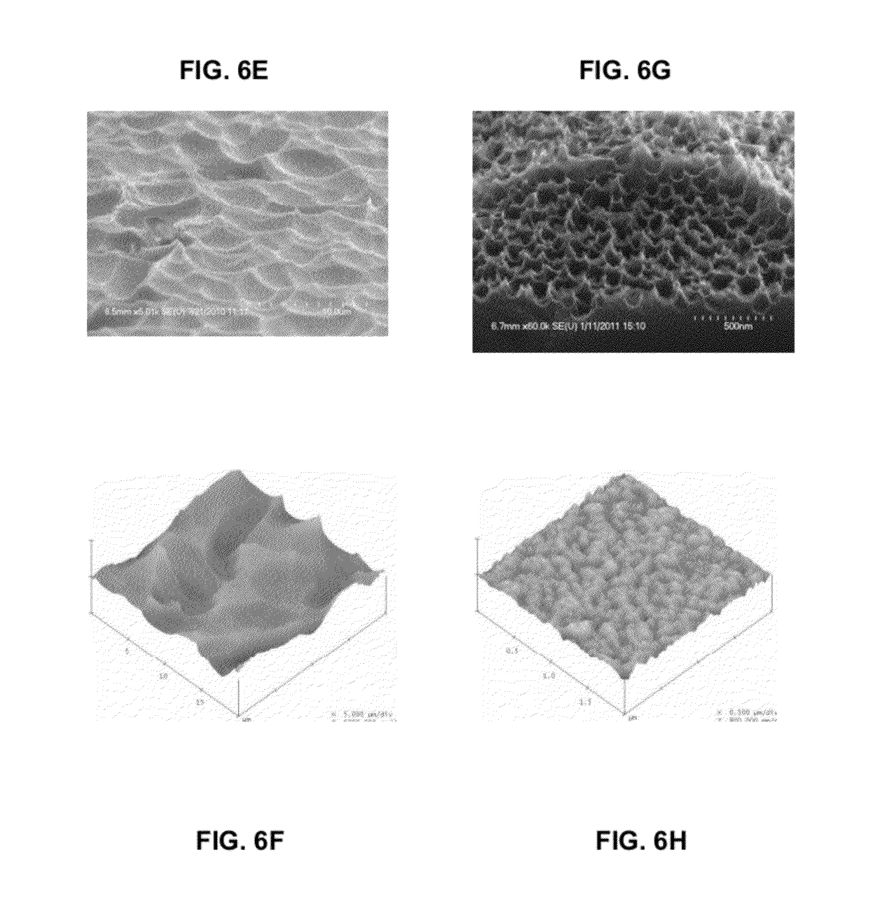

FIGS. 6A-6B illustrate the wafer as cut, FIGS. 6C-6D illustrate the wafer after saw damage removal (SDR), and FIGS. 6E-6F illustrate the wafer after post dry etch. The texture size shown in FIGS. 6E-6F is about 100 nm. SDR removes the mechanically damaged silicon layer (damaged during the cutting process). SDR is typically done using a diamond saw-type sawing machine, and is typically followed by a wet texturing process.

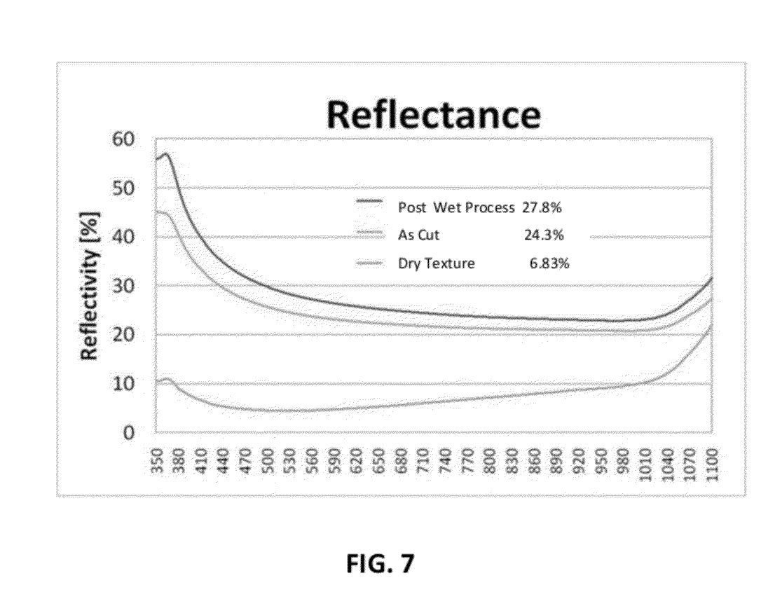

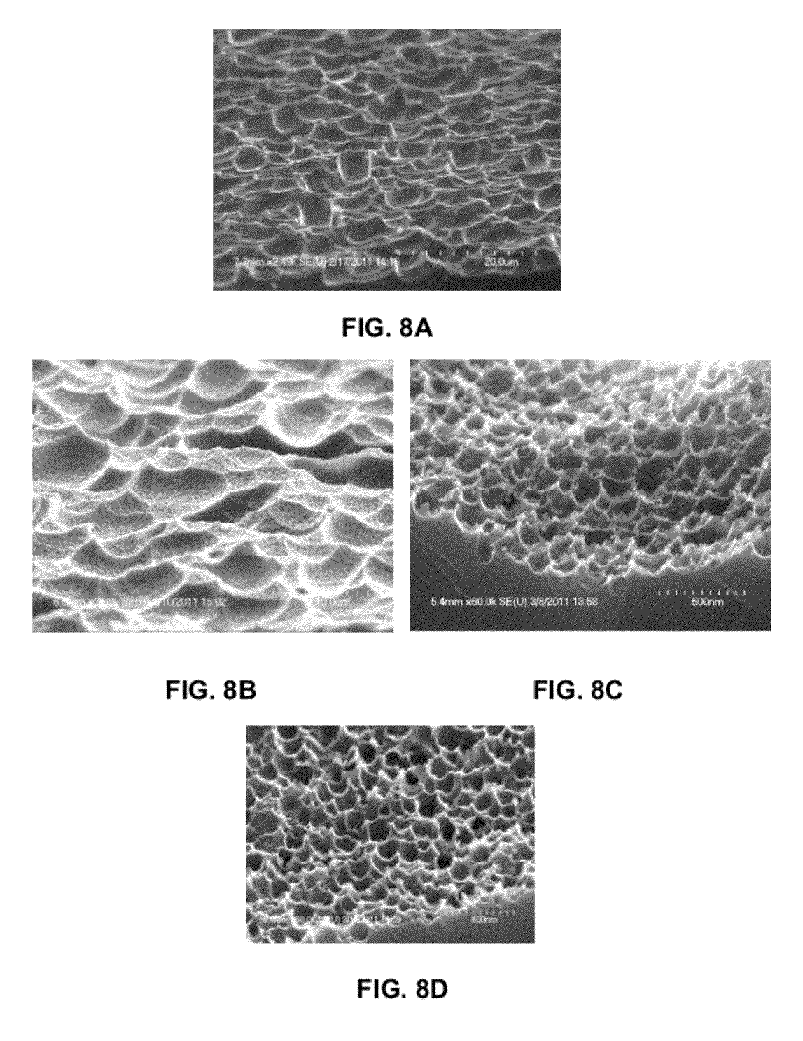

FIG. 7A illustrates reflectance of the surface after saw damage removal (23.6% reflectance), after saw damage removal and dry etch (11.4% reflectance) and after saw damage removal, dry etch and cleaning (11.8% reflectance). FIGS. 8A-8D show the wafer surface after saw damage removal (FIG. 8A), after dry etching (FIGS. 8B-8C) and after residual removal (FIG. 8D).

It will be appreciated that although the above process has been described primarily with reference to a silicon substrate or wafer, the substrate or wafer may be made of other materials commonly used in the semiconductor or solar industry. One of skill in the art will understand that the above processes may be adapted to such different materials.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A system comprising:
a silicon etch chamber to perform a first etch process to remove a portion of a silicon oxide layer on a silicon wafer and a second etch process that is highly selective of silicon to oxide.

2. The system of claim 1, further comprising an oxidation chamber to form the silicon oxide layer on a surface of a silicon wafer.

3. The system of claim 2, wherein the oxidation chamber is a plasma oxidation chamber.

4. The system of claim 2, wherein the oxidation chamber is coupled to the silicon etch chamber so the silicon oxide layer is formed on the surface of the silicon wafer before the wafer enters the silicon etch chamber.

5. The system of claim 1, further comprising a wafer loading chamber and a wafer unloading chamber.

6. The system of claim 5, further comprising a loadlock between the wafer loading chamber and the plasma oxidation chamber, and a loadlock between the silicon etch chamber and the wafer unloading chamber.

7. A method of making a silicon wafer having a textured surface comprising:
performing a first silicon etch process on a silicon wafer having an oxide layer; and
performing a second silicon etch process on the silicon wafer, wherein the second silicon etch process is more selective etching of silicon to oxide.

8. The method of claim 7, further comprising performing a surface oxidation process on a silicon wafer to grow the oxide layer before performing the first silicon etch process.

9. The method of claim 8, wherein the surface oxidation process comprises plasma oxidation.

10. The method of claim 7, wherein the first and second silicon etch processes comprise dry etching.

11. The method of claim 10, wherein the dry etching comprises one of reactive ion etching, plasma etching and physical sputtering.

12. The method of claim 7, wherein the second silicon etch process comprises an anisotropic etch process.

13. A solar cell made by the process of claim 7.

14. A method comprising:
etching a silicon oxide layer on a silicon wafer having defect sites and non-defect sites to remove at least the portion of the silicon oxide layer over the non-defect sites; and
selectively etching the wafer.

15. The method of claim 14, further comprising growing the silicon oxide layer before etching the silicon oxide layer.

16. The method of claim 15, wherein growing the silicon oxide layer comprises oxidizing the silicon wafer.

17. The method of claim 14, wherein the silicon oxide layer is thicker over the defect sites than over the non-defect sites.

18. The method of claim 14, wherein etching the silicon oxide layer comprises dry etching the silicon oxide layer.

19. The method of claim 14, wherein selectively etching the wafer comprises dry etching the wafer.

20. A solar cell made by the process of claim 14.
